(19) United States
(12) Patent Application Publication
(10) Pub. No.: US 2024/0063086 A1
(43) Pub. Date: Feb. 22, 2024

(54) Monatomic Single-Entity Baseplate Structure Employing a Thermoplastic Polyimide Bondline Between a Silicon Substrate and a Metallic Heat Sink Having Mismatched Coefficients of Thermal

(71) Applicant: James B. Fraivillig, Boston, MA (US)

(72) Inventor: James B. Fraivillig, Boston, MA (US)

(21) Appl. No.: 18/384,052

(22) Filed: Oct. 26, 2023

(51) Int. Cl. H01L 23/373

(52) U.S. Cl. CPC H01L 23/3737; H01L 23/3735

(57) ABSTRACT

An ultra-thin robust bondline of thermoplastic polyimide (TPI) adhesive is disposed directly between a layer of silicon and a metallic layer to create a silicon/metal monatomic baseplate providing a heat sink structure for mounting semiconductors in electronic circuits.

### BACKGROUND OF THE INVENTION

### Field of the Invention

The invention resides in the field of heat sink mounting assemblies for semiconductors in electronic circuits and more particularly relates to silicon and metallic structures having mismatched coefficients of thermal expansion, but when conjoined perform in a monatomic nature, or as one entity.

### Description of the Prior Art

At the heart of power electronics, semiconductors convert electricity to different formats, which generate waste heat from inherent inefficiencies. This heat must be dissipated from the system to prevent the semiconductors from overheating. Passive thermal management requires the intimate contact of hot semiconductors and their substrates to cooling layers, while maintaining dielectric separation. Attachment of power semiconductors and substrates is done with thin layers of thermal-interface materials (TIMs), such as thermal grease, which maximize thermal transfer by eliminating air in the bondline. Additionally, inorganic filler in the TIM layer—such as ceramic or metal particles—is known to boost thermal conductivity. TIM layers can also provide lamination adhesion, as well as dielectric separation. Non-adhesive TIM layers require pressure from attachment hardware to ensure laminate intimacy.

There are two main structures in power-electronic packaging: silicon die semiconductors and metallic heat sinks, preferably aluminum. Power semiconductors, the heat generators, have low coefficients of thermal expansion (CTE) and are brittle. Aluminum components, the ultimate heat dissipator, have a high CTE and are relatively robust and ductile. In fact, silicon has the lowest CTE of any standard electronic packaging material, 2.6 ppm/C, while aluminum has the highest, 23 ppm/C. Conventionally, this CTE mismatch between the semiconductors and the aluminum heat sinks requires a number of interlayers to step-down the CTE during operation to prevent semiconductor delamination with thermal cycling. These CTE buffer interlayers can be made of ceramic, metal or even plastic, with TIM layers required at every interface.

As disclosed in applicant's U.S. Pat. No. 10,253,228, thermoplastic polyimide (TPI) adhesive bond lines allow the direct bonding of low-CTE materials, such as semiconductors, to high-CTE metallic heat sinks, generally made of aluminum or aluminum alloy. This technology dramatically reduces thermal resistance within power electronic packages, improving performance while reducing cost, complexity, space and weight.

Most power electronics packages require passive cooling to an aluminum heat sink through a thermal-interface bond line. In traditional designs, the vast coefficient of thermal expansion differences between heat-generating semiconductors and aluminum generally necessitate an intermediate electronic package consisting of CTE-ascending layers of substrates such as ceramic, copper or plastic to step-down the CTE mismatch to prevent delamination resulting from the stresses of thermal cycling. Mating the final power electronic package to the heat sink or spreader with a mixture of relatively thick and soft thermal interface materials can be very non-monatomic, generally requiring attachment hardware to secure the multiple entities or components together.

Bonding the power-electronic package directly to the baseplate or heat sink with highly-filled thermoset adhesives simplifies the design, but would lead to eventual bondline failure, and the loss of thermal transfer, as the brittle thermoset adhesive cracks with the stresses of thermal cycling the CTE-mismatched subassembly.

Bondlines with thermoplastic polyimide (TPI) adhesive remain ductile, even when highly filled. However, conventional amorphous TPI bondlines have very limited shear strength above their polymer glass-transition temperatures (Tg), which limits their usefulness. In contrast, the above cited patented TPI adhesive process and system retains robust shear strength and adhesion far above its Tg, due to its straight-chain/rigid-rod polymer structure, similar to Kapton® film, and its propensity to orient and crystallize, without becoming brittle.

Additionally, TPI bondlines, as both an adhesive and dielectric, can withstand continuous operation at over 300° C. down to cryogenic, and survive extreme liquid-to-liquid thermal shocks. Also, it is important to note that enabling high-temperature operation significantly reduces system cooling requirements.

TPI bondlines are effective in thicknesses down to a few microns, depending on the surfaces' topographies, and can accept inorganic compounding up to 30-40% by volume, enabling maximum thermal transfer to minimize semiconductor operating temperature. A 3 um-bondline with 80%-by-weight silver (bulk thermal conductivity of about 3 W/mK) has a thermal impedance of only about 0.002° C.-in²/W. If an insulation layer is required, ceramic-filled TPI bond lines have dielectric strengths of about 140 V/um and a bulk thermal conductivity of about 1 W/mK.

### SUMMARY OF THE INVENTION

The present invention, in contrast to the above described process of mounting semiconductors or chips on metallic heat sinks, discloses the alternative of large-area silicon/metallic substrates, preferably silicon-aluminum (Si-Al) substrates, where a single large-footprint die, or multiple surface-mounted chips or devices, can populate a silicon-dielectric laminated plane, without concern for CTE mismatch.

The ability to directly bond semiconductor die or even large-area silicon substrates to aluminum substrate baseplates streamlines power-electronic packaging design and construction, reducing cost, space, weight and complexity, while improving thermal-management performance. The simplicity of Si-on-Al lamination also minimizes required package processing and SKUs.

The TPI bondline also enables continuous operation above 250° C. which would significantly reduce cooling requirements versus the conventional 125-150° C. maximum junction temperature (Tⱼ) of a silicon semiconductor. Silicon carbide (SiC) semiconductors, for instance, can operate at 250° C. and above, which would reduce the system cooling load by about 60% versus a maximum of 125° C. As cooling is one of the biggest cost and technical considerations in power-electronic systems, this feature could be especially attractive, allowing passive cooling by conduction and natural convection rather than active cooling methods with forced air or water in clumsy and costly processing and fixturing in channeled heat sinks.

As solid-state Si-on-Al lamination has not been possible in the past, electronic-packaging designers have not yet explored ways to utilize the unique capability and resultant properties in totally new applications. For instance, the CTE mismatch ensures that the semiconductor layer is in compression on the aluminum substrate below the bonding temperature of 250° C. This feature could be advantageous in attaching semiconductor chips to a silicon-aluminum plate, where they can operate stress-free. The Si-on-Al substrate absorbs the stress.

Also exposing the Si-on-Al laminate to temperatures higher than the bonding temperature of, say, 250° C. would have the higher-CTE aluminum expanding rather than compressing the semiconductor wafer, which could have processing advantages, such as in doping.

The inherent structural forces within the CTE-mismatched lamination between the low-CTE silicon and high-CTE aluminum provides a novel heat-sinking capability, in particular, the energy that is consumed in deforming or reforming the Si-on-Al laminate during temperature excursions does not manifest itself as heat, moderating the operating temperature of mounted or embedded one or more semiconductors on or in the silicon to prevent damage.

As shown in FIG. 6, the CTE-deforming effect is evident on Si-on-Al laminations having thin layers of both silicon 30 and aluminum 32 sheets. As this CTE-mismatched lamination was bonded as flat at 250° C., it warps towards the aluminum upon cooling, as the high-CTE aluminum shrinks much more than the silicon. It is interesting to note that silicon wafer is, on its own, very brittle, but bends into an arc with the commensurate consistent force of the shrinking aluminum. As a Si-on-Al laminate heats up, the bowing will alleviate, eventually flattening out at the bond temperature.

This CTE-deformation effect or force is much less pronounced on thicker laminates, such as the solid-state baseplate of the invention, but still exists. The energy consumed to change the physical characteristics of the laminate would therefore not be available to heat the laminate and any attached components, and so would help reduce the temperature on any operating semiconductor die on or in the silicon.

As noted, laminating silicon wafer to aluminum to make thick composite structures that do not bow results in the semiconductor being in compression at room temperature, as the aluminum shrinks nearly ten times faster than the silicon. Having silicon in compression while mounted on its aluminum carrier could have advantages in processing such as doping.

To test the efficacy of a bond, a resulting lamination is heated to 300° C. (hot plate, oven, or solder pot) and then dunked into ice water. If the TPI bondline has any imperfection that makes it vulnerable, the severe thermal shock will cause the aluminum heat sink and silicon wafer to begin to separate after which the wafer can be easily removed undamaged with finger pressure and then be reworked. When the TPI bondline survives this worst-case stress test, it is certain that the silicon wafer and aluminum heat sink are securely attached.

Potential application examples are as follows:

Server farms: bonding a server CPU semiconductor directly to aluminum would allow the use of much larger-footprint CPUs in servers, increasing their computing capacity. This would reduce the number of required units in a server farm. Operating the CPUs at considerably higher temperatures would significantly reduce the cooling load, a big cost factor in both required equipment and processing.

Ultra-high-power LEDs: bonding LED semiconductors directly to aluminum plate, maximizing thermal dissipation, would allow much larger and denser chips. The backside of the aluminum substrate, a single bondline away from the LED die, would enable liquid or phase-change cooling.

### DESCRIPTION OF THE DRAWINGS

FIG. 1 is an illustration of the prior art;

FIG. 2 is a schematic representation of the preferred embodiment of the invention;

FIG. 3 is a perspective view of the preferred embodiment of the invention;

FIG. 4 is an additional perspective view of the preferred embodiment of the invention;

FIG. 5 is an another perspective view of the preferred embodiment of the invention; and

FIG. 6 is a perspective view of the preferred embodiment of the invention in a processed state.

### DESCRIPTION OF THE PREFERRED EMBODIMENT

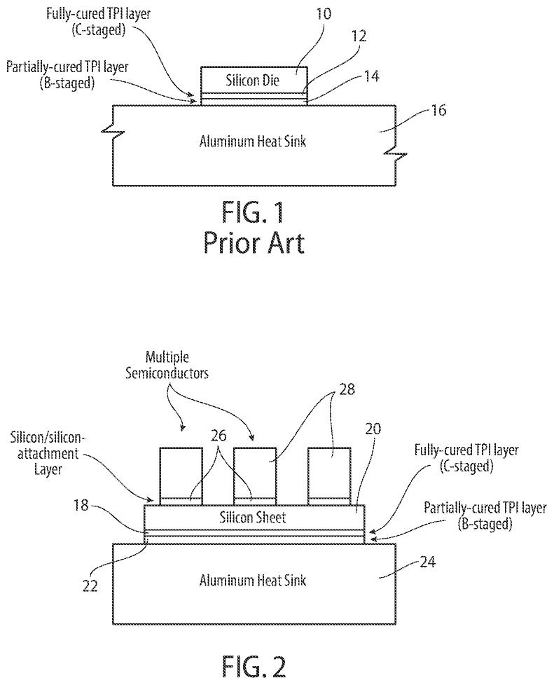

Referring to FIG. 1, the prior art as disclosed in US patent 10,253.228 is shown for comparison with the present invention in which liquid A-staged TPI primer layer is applied to a semiconductor 10, after which heat is applied to drive off the solvent and dry and cure the TPI coating 12. This process can be done with conventional ovens, vacuum ovens, hot plates and radiant heaters. To ensure the full curing or C-staging of the initial TPI coating 12 on the semiconductor surface, a high temperature bake is required, generally at least at 230° C. to ensure imidization.

A second thicker liquid A-staged layer of TPI 14 is then applied to the C-staged layer 12 and then partially cured to a B-stage by baking at much more moderate temperatures, generally at between 70 and 120° C., ensuring the polymer reactivity required to adhere to the aluminum surface during lamination. While the initial TPI layer on the semiconductor is ultra-thin and unfilled, the second A-staged layer would be thicker, to accommodate for surface imperfections in the semiconductor and especially heat sink, and can be compounded with inorganic filler, such as metal or ceramic powder, to enhance thermal performance.

Additionally, a very thin liquid A-staged priming layer of TPI may be directly applied to the aluminum heat sink 16, and then B-staged dried at 70-120° C., to ensure an optimal bonding surface.

In accordance with the present invention as shown in FIG. 2, a minimal primer coating liquid A-staged TPI 18 is applied to the silicon sheet or layer 20, after which heat is applied to drive off the solvent and dry and cure the TPI coating. This process can be done with conventional ovens, vacuum ovens, hot plates and radiant heaters. To ensure the full curing or C-staging of the initial TPI coating on the silicon layer surface, a high temperature bake is required, generally at least at 230° C. The adhesion and durability-in-use of this anchorage C-stage layer can be enhanced with even greater temperatures, as that not only ensures full curing but also some crystallization.

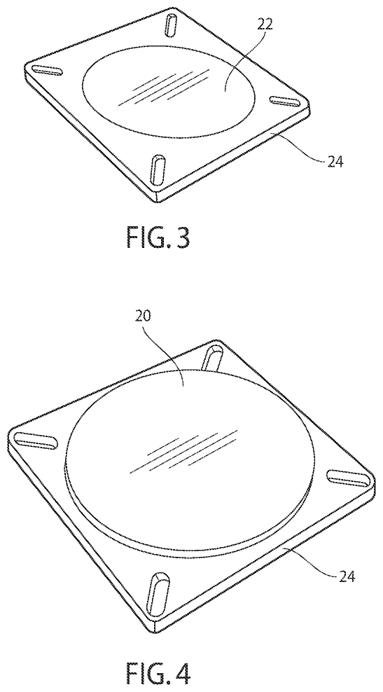

A thicker second liquid A-staged layer 22 of TPI, needed to compensate for the laminate's surface micro-irregularities, is then applied to the C-staged layer and then partially cured to a B-stage by baking at more moderate temperatures, generally at between 70 and 120° C., ensuring the polymer reactivity required to adhere to the aluminum surface during lamination. Alternatively, the second liquid A-staged priming layer 22 of TPI may be directly applied to the aluminum heat sink 24 as illustrated in FIG. 3, and dried to B-stage.

The TPI polymer coating has been shown to be effective as a one-part, spin-coatable die-attach adhesive 26 applied to the backside of semiconductor wafers 28 before unitizing. The TPI adhesive layers are dried and B-staged/C-staged after coating with temperature exposure for a few minutes, and then has infinite shelf-life at room temperature. The TPI-coated semiconductor chips can then be thermo-compression bonded with pick-and-place automation within seconds to an aluminum, or any compatible, surface at 250° C. These robust polyimide bonded die have shear strengths of 10-20 MPa resulting in minimal degradation due to extreme-condition exposure.

Referring to FIGS. 3-5, there is shown a monatomic baseplate of the invention 28 created by the thermo-compression of a 50-mm wide, 2-mm thick wafer of silicon and a 55-mm square of aluminum at 250° C. following the above process steps.

FIG. 3 illustrates the B-staged TPI primer layer 22 directly applied to heat sink 24 as disclosed above.

FIG. 4 shows the completed silicon/metal monatomic single entity baseplate of the invention.

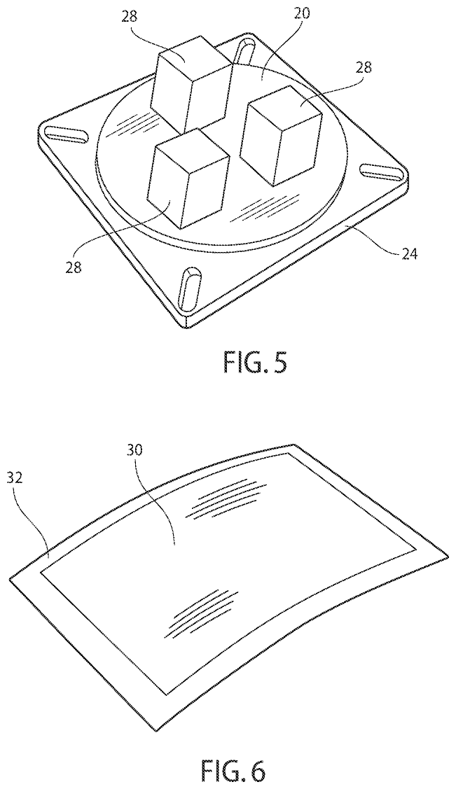

FIG. 5 is an additional illustration of the novel baseplate of the invention further showing a plurality of separate semiconductors 28 mounted thereon.

1. A silicon/metal monatomic baseplate heat sink structure for mounting semiconductors in electronic circuits comprising in combination:
A. a top sheet having an upper surface and an under surface, said top sheet comprising a silicon sheet of a size sufficient to attach to, mount, and support a plurality of electrical circuit semiconductors; and
B. a bottom sheet having an upper surface and an under surface comprising a metallic sheet, said bottom sheet upper surface adhesively attached, by an ultra-thin robust bondline of thermoplastic polyimide (TPI), to said top sheet under surface providing a heat sink for said top sheet and any semiconductors mounted thereon.

2. The baseplate of claim 1 wherein said bottom sheet is composed of aluminum.

3. The base plate of claim 1 wherein, in combination, a plurality of semiconductors are mounted on said top sheet upper surface by a silicon/silicon attachment layer.
